(19) United States
(12) Patent Application Publication
(10) Pub. No.: US 2013/0002297 A1
(43) Pub. Date: Jan. 3, 2013

(54) BIAS TEMPERATURE INSTABILITY-RESISTANT CIRCUITS

(75) Inventors: Palkesh Jain, Bangalore (IN); Francisco Adolfo Cano, Sugar Land, TX (US)

(73) Assignee: TEXAS INSTRUMENTS, INCORPORATED, Dallas, TX (US)

(21) Appl. No.: 13/492,738

(22) Filed: Jun. 8, 2012

Related U.S. Application Data
(60) Provisional application No. 61/502,137, filed on Jun. 28, 2011.

(51) Int. Cl. H03K 19/02; H03K 19/21; H03K 19/096

(52) U.S. Cl. 326/52; 326/93; 326/95

(57) ABSTRACT

A Bias Temperature Instability- (BTI-) resistance circuit is arranged to propagate a received clock signal through a clock tree. The state of the clock signal is inverted at a midpoint of the clock tree that is about the halfway point of the path of the propagated clock signal through the clock tree. The inversion of the clock signal at the midpoint mitigates BTI-aging effects of the BTI-resistant circuit when the clock signal is blocked by a clock gating signal, for example. The clock tree can be used to latch a data signal at an input latch of a logic block using the received clock signal, and to latch a data signal at an output latch of a logic block using a propagated clock signal that is output from the endpoint of the clock tree.

### CLAIM OF PRIORITY

This application for Patent claims priority to U.S. Provisional Application No. 61/502,137 (attorney docket TI-68382PS) entitled “3 NOVEL ASYMMETRIC-AGING TOLERANT CLOCK ARCHITECTURES” filed Jun. 28, 2011, wherein the application listed above is incorporated by reference herein.

### BACKGROUND

Bias Temperature Instability- (BTI-) induced degradations is a cause of semiconductor product aging. While negative BTI (NBTI) induced degradations predominantly affect PMOS (P-type metal-oxide-semiconductor) transistors, positive BTI (PBTI) induced degradations predominantly affect NMOS (n-type metal-oxide-semiconductor) transistors. Complementary MOS (CMOS) technology is thus subject to BTI-induced degradations. The degree of BTI-induced degradation varies in accordance with the amount of the stress voltage, temperature and duration of waveform transitions, the age of the transistors, and characteristics of the transistors being stressed such as the threshold voltage (Vt) and drive current (Idsat), which both degrade over time.

Thus, circuit designers analyze the performance of their circuit/critical paths using End-of-Life (EoL) considerations. However, the analysis of the EoL considerations is non-trivial because the extent and the (e.g., system) impact of aging greatly depends on the history of operations, including voltage levels used, bit patterns, slew rates, duty cycles, and the temperatures in which the circuits are used. Often, the circuits that are most greatly impacted by BTI-induced degradations are power-managed clocks, which are often placed into a power-down mode based in accordance with the state of the gating logic.

### SUMMARY

The problems noted above are solved in large part by a Bias Temperature Instability- (BTI-) resistance circuit is arranged to propagate a received clock signal through a clock tree. The state of the clock signal is inverted at a midpoint of the clock tree that is about the halfway point of the path of the propagated clock signal through the clock tree. The inversion of the clock signal at the midpoint mitigates BTI-aging effects of the BTI-resistant circuit when the clock signal is blocked by a clock gating signal, for example. The clock tree can be used to latch a data signal at an input latch of a logic block using the received clock signal, and to latch a data signal at an output latch of a logic block using a propagated clock signal that is output from the endpoint of the clock tree. Both positive BTI- (PBTI-) aging effects and negative (NBTI-) aging effects can be mitigated in accordance with the teachings herein.

### BRIEF DESCRIPTION OF THE DRAWINGS

FIG. 1 shows an illustrative computing device in accordance with embodiments of the disclosure;

FIG. 2 is a schematic diagram illustrating NBTI-induced aging;

FIG. 3 is a schematic diagram illustrating a circuit that includes a conventional clock-tree;

FIG. 4 is a schematic diagram illustrating a circuit that includes a forced dual-inversion NBTI-resistant clock-tree 400 in accordance with embodiments of the disclosure;

FIG. 5 is a schematic diagram illustrating a circuit that includes a secondary clock gate insertion NBTI-resistant clock-tree 500 in accordance with embodiments of the disclosure; and

FIG. 6 is a schematic diagram illustrating a circuit that includes clock-tree non-equivalent gate insertion NBTI-resistant clock-tree 600 in accordance with embodiments of the disclosure.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Certain terms are used throughout the following description—and claims—to refer to particular system components. As one skilled in the art will appreciate, various names may be used to refer to a component. Accordingly, distinctions are not necessarily made herein between components that differ in name but not function. In the following discussion and in the claims, the terms “including” and “comprising” are used in an open-ended fashion, and thus are to be interpreted to mean “including, but not limited to . . . . ” Also, the terms “coupled to” or “couples with” (and the like) are intended to describe either an indirect or direct electrical connection. Thus, if a first device couples to a second device, that connection can be made through a direct electrical connection, or through an indirect electrical connection via other devices and connections.

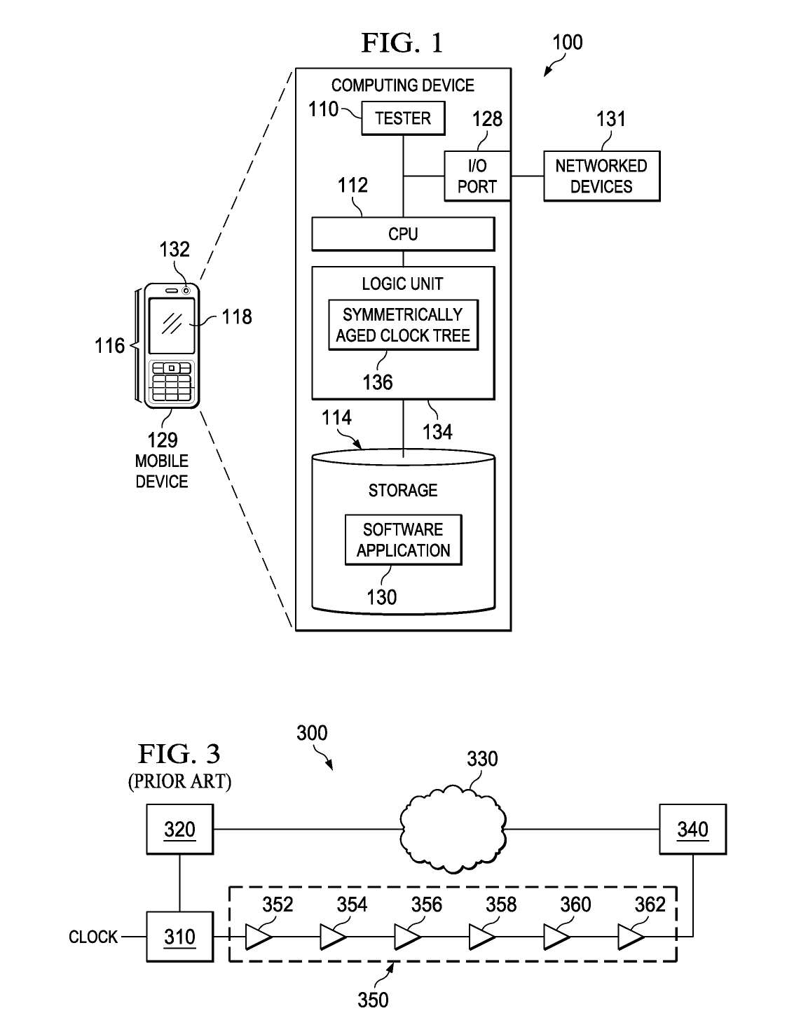

FIG. 1 shows an illustrative computing device 100 in accordance with embodiments of the disclosure. For example, the computing device 100 is, or is incorporated into, a mobile communication device 129, such as a mobile phone, a personal digital assistant (e.g., a BLACKBERRY® device), a personal computer, automotive electronics, projection (and/or media-playback) unit, or any other type of electronic system.

In some embodiments, the computing device 100 comprises a megacell or a system-on-chip (SoC) which includes control logic such as a CPU 112 (Central Processing Unit), a storage 114 (e.g., random access memory (RAM)) and tester 110. The CPU 112 can be, for example, a CISC-type (Complex Instruction Set Computer) CPU, RISC-type CPU (Reduced Instruction Set Computer), or a digital signal processor (DSP). The storage 114 (which can be memory such as on-processor cache, off-processor cache, RAM, flash memory, or disk storage) stores one or more software applications 130 (e.g., embedded applications) that, when executed by the CPU 112, perform any suitable function associated with the computing device 100. The CPU 112 can include (or be coupled to) logic unit 134, which includes synchronous (or asynchronous) logic arranged in a common (or separate) substrate. Logic unit 134 includes a symmetrically aged clock tree 136 that provides protection for critical transistors against BTI-induced degradations as disclosed herein below.

The tester 110 is a diagnostic system and comprises logic (embodied at least partially in hardware) that supports monitoring, testing, and debugging of the computing device 100 executing the software application 130. For example, the tester 110 can be used to emulate one or more defective or unavailable components of the computing device 100 to allow verification of how the component(s), were it actually present on the computing device 100, would perform in various situations (e.g., how the components would interact with the software application 130). In this way, the software application 130 can be debugged in an environment which resembles post-production operation.

The CPU 112 comprises memory and logic that store information frequently accessed from the storage 114. The computing device 100 is often controlled by a user using a UI (user interface) 116, which provides output to and receives input from the user during the execution the software application 130. The output is provided using the display 118, indicator lights, a speaker, vibrations, image projector 132, and the like. The input is received using audio and/or video inputs (using, for example, voice or image recognition), and mechanical devices such as keypads, switches, proximity detectors, and the like. The CPU 112 and tester 110 is coupled to I/O (Input-Output) port 128, which provides an interface (that is configured to receive input from (and/or provide output to) peripherals and/or computing devices 131, including tangible media (such as flash memory) and/or cabled or wireless media (such as a Joint Test Action Group (JTAG) interface). These and other input and output devices are selectively coupled to the computing device 100 by external devices using wireless or cabled connections.

In view of the teachings disclosed herein, the effects of BTI-induced degradations and system designs are substantially alleviated by selectively using positive or negative logic (e.g., inversions) in portions of a clock-tree during operation of a circuit of a target system as functional replacements to ensure symmetric aging of transistors in the clock-tree.

Negative Bias Temperature Instability- (NBTI-) and Channel Hot Carrier- (CHC-) induced degradations are primary causes of product aging. While NBTI-induced degradations typically affect PMOS transistors, CHC-induced degradations typically occur in both NMOS and PMOS transistors. The degree of NBTI- and CHC-induced degradations is a function of (for example) the stress voltage, gate temperature, and duration of hold times after state transitions, and the age of transistors. Thus the threshold voltage (Vt) and drive current (Idsat) of the transistors (stressed by the NBTI- and CHC-induced degradations) degrade with time.

Accordingly designers perform End of Life (EoL) analyses of the performance of their circuit/critical paths. The analyses typically make simplified assumptions to ease the calculations that would otherwise be required to perform an accurate analysis. One such approach that each transistor of the design degrades by the same amount (e.g., 50 mV over a lifetime of 10 years), and this information is relied upon to construct an EoL Model, which is used for timing characterization of a design.

Thus the analyses using simplifying assumptions result in tolerances (which affect cost and performance) that are larger than they might otherwise be. For example, designers may have to reduce the clock speed by 10 percent or more to provide a safety margin that allows for a gradual decrease in the maximum operating frequency of the implemented design as the circuits age. Failure to provide the safety margin increases the chances of functional failures induced due to pulse width distortion and greater insertion delays.

Improving the accuracy of the EoL analyses is non-trivial because the extent of aging and the impact of aging largely depend on the actual history of operations, including the voltage level, bit patterns, slews, duty cycles and temperatures that are used (and/or encountered) in an actual application. Consequently, power-managed clocks are subject to a large amount of variance in the degree of NBTI- and CHC-induced degradations because power-managed clocks are often forced into a power-down state based on the gating logic. Clock gating typically results in asymmetric aging because gating a clock induces NBTI aging on only one of the edges of the clock (due to the PMOS transistors used in a clock tree, for example).

As disclosed herein, power-managed clocks includes NBTI- and CHC-induced degradation mitigation circuitry in the clock (and/or clock tree), which ensures that even while the clock signal remains in a gated state (as a result of a power-mode signal asserted by logic unit 134, for example), the gating logic is arranged to age the transistors in a selected portion of symmetrically aged clock tree 136. Thus, substantial changes in circuit design to mitigate the NBTI- and CHC-induced degradation are avoided as are typically encountered when using mitigation approaches such as using low frequency clocks.

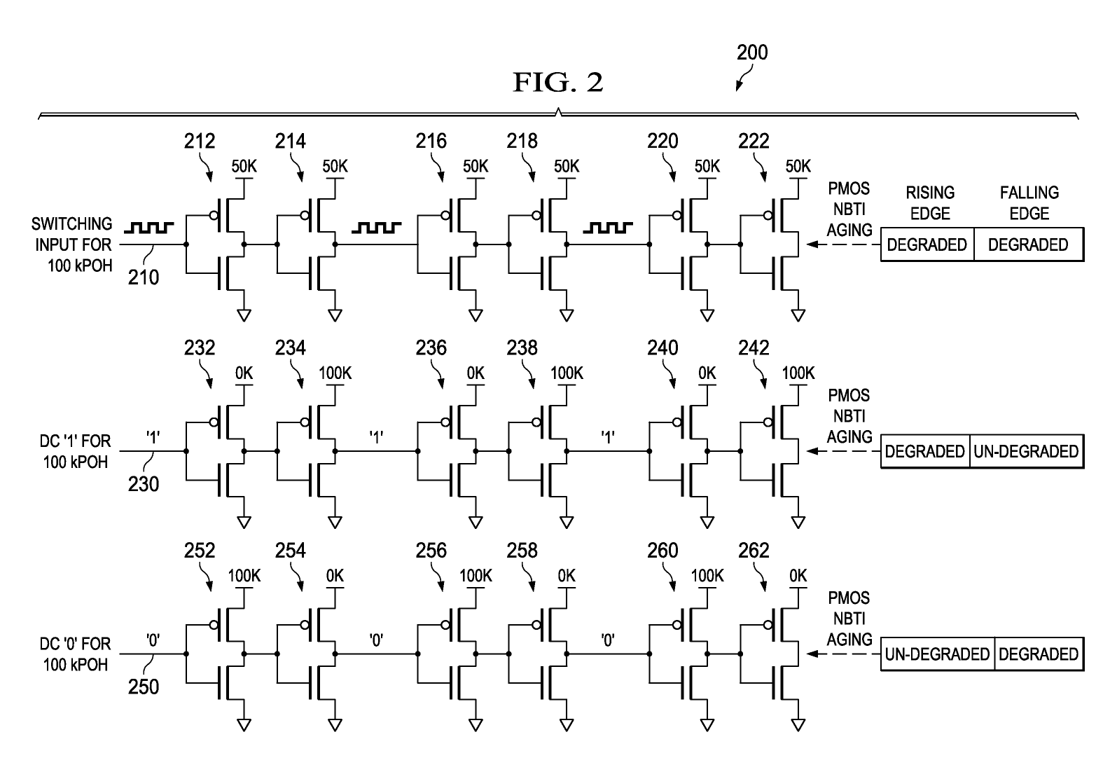

FIG. 2 is a schematic diagram illustrating NBTI-induced aging. Circuit 200 illustrates NBTI-induced aging in digital CMOS circuits. Server 200 includes clock tree 210, clock tree 230, and a clock tree 250. Clock tree 210 includes inverter 212 and inverter 214 (which together form a non-inverting buffer), inverter 216 and inverter 218 (which form a second non-inverting buffer), and inverter 212 and an inverter 222 (which form a third of non-inverting buffer). The input of clock tree 210 is coupled to a switching input that is applied to clock tree 210 for 100,000 power-on hours (100 kPOH). The clock tree 210 illustrates that each PMOS transistor is active for 50 kPOH. Thus, NBTI-induced aging is evenly distributed amongst each of the PMOS transistors and each rising edge and each falling edge of the clock signal is affected evenly.

Clock tree 230 illustrates state dependent NBTI-induced aging. Clock tree 230 includes inverters 232, 234, 236, 238, 240, and 242. The input clock tree 230 is coupled to a non-switching input (a direct current voltage that represents a logic one, for example) that illustrates an operating state that is encountered when a power-managed clock is gated. In the illustrated state, PMOS transistor in inverter 234, the PMOS transistor in inverter 238, and the PMOS transistor in inverter 242 are in the “on” state for 100 kPOH, whereas the PMOS transistor inverter 232, the PMOS transistor inverter 236, and the PMOS transistor inverter 240 are in the “off” state (and thus do not accrue any power-on hours). Thus, each PMOS transistor in a pair of PMOS transistors of each non-inverting buffer is aged unevenly when the clock signal in clock-tree 230 is gated. Thus, NBTI-induced aging is unevenly distributed amongst each of the PMOS transistors such that each rising edge of the clock signal is degraded, whereas each falling edge of the clock signal remains unaffected.

Clock tree 250 illustrates state dependent NBTI-induced aging. Clock tree 250 includes inverters 252, 254, 256, 258, 260, and 262. The input clock tree 250 is coupled to a non-switching input (a direct current voltage that represents a logic one, for example) that illustrates an operating state that is encountered when a power-managed clock is gated. In the illustrated state, PMOS transistor in inverter 252, the PMOS transistor inverter 256, and the PMOS transistor inverter 260 are in the “on” state for 100 kPOH whereas the PMOS transistor inverter 254, the PMOS transistor in inverter 258, and the PMOS transistor in inverter 262 are in the “off' state (and thus do not accrue any power-on hours). Thus, PMOS transistor in a pair of PMOS transistors of each non-inverting buffer is aged unevenly when the clock signal in clock-tree 250 is gated. Thus, NBTI-induced aging is unevenly distributed amongst each of the PMOS transistors such that each falling edge of the clock signal is degraded, whereas each rising edge of the clock signal remains unaffected.

Accordingly, when a power-managed clock-tree is gated (e.g., such that the clock signal transitions are not propagated), the PMOS transistors in an inverter having an input of “0” continuously age, the PMOS transistors in an inverter having the input of “1” do not age. Thus, each pair of PMOS transistors in a non-inverting buffer develop, for example, an unequal switching times, which progressively lowers the maximum operating frequency of the clock propagated by the clock-tree.

FIG. 3 is a schematic diagram illustrating a circuit that includes a conventional clock-tree. Circuit 300 includes an input clock buffer 310. Input clock buffer 310 is arranged to couple the clock signal to input logic circuit 320 as well as to a clock-tree 350 formed by non-inverting buffers 352, 354, 356, 358, 360, and 362. Input logic circuit 320 is arranged to propagate a logic output signal to an input of combinatorial logic 330 in response to the received clock signal. Output logic block 340 is arranged, for example, to latch an output from combinatorial logic 330 in response to the clock input signal received from the output of non-inverting buffer 362. Accordingly, the PMOS transistors in clock tree 350 are aged unevenly (due to NBTI-induced aging) such that the output logic block 340 may erroneously latch the state of the output from combinatorial logic 330.

When clock-tree 350 is gated such that the output of clock-tree 350 is a logic zero, the falling edge of the output signal of the clock-tree is degraded over time. In contrast, when clock tree 350 is gated such that the output of clock-tree 350 is a logic one, the rising edge of the output signal of the clock-tree is degraded over time. In an example set of operating conditions, the clock skew of clock-tree 350 due to NBTI-induced aging is estimated to be around 10 percent between the launch (e.g., a first transition of the output of input clock buffer 310) and the capture clock (e.g., the first transition of the input of output logic block 340).

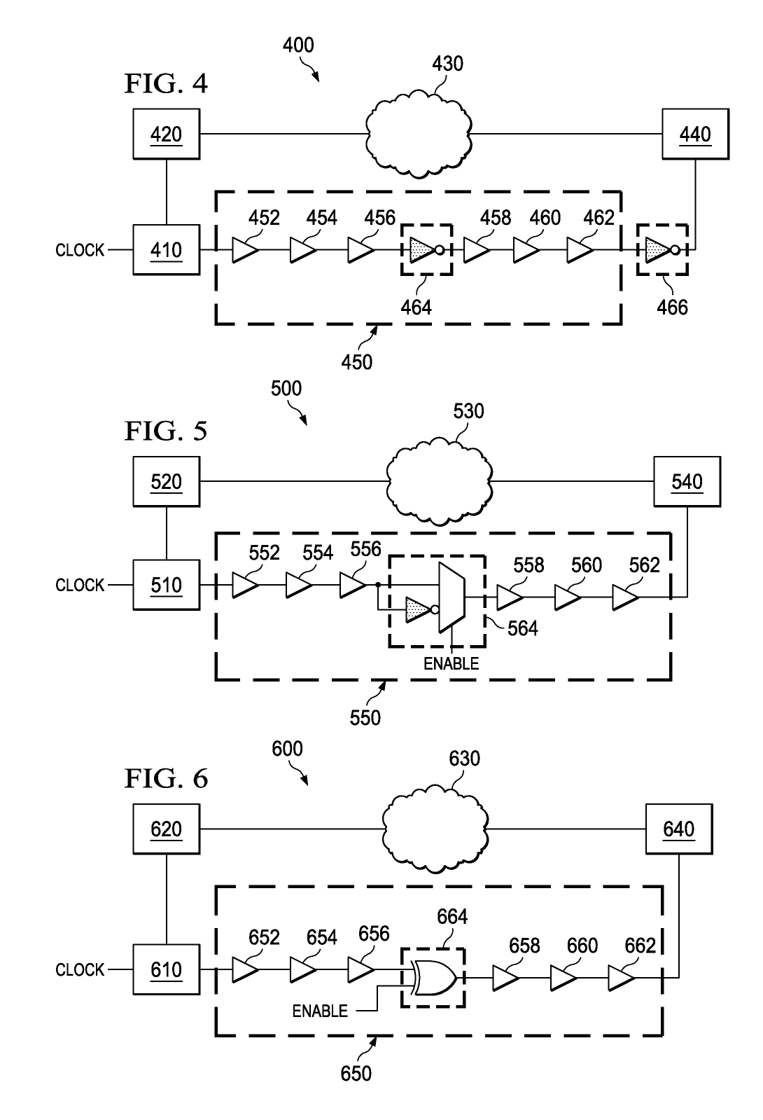

FIG. 4 is a schematic diagram illustrating a circuit that includes a forced dual-inversion NBTI-resistant clock-tree 400 in accordance with embodiments of the disclosure. Circuit 400 includes an input clock buffer 410. Input clock buffer 410 is arranged to couple the clock signal to input logic circuit 420 as well as to a clock-tree 450 formed by non-inverting buffers 452, 454, 456, 458, 460, and 462. The clock-tree 450 is divided into two portions with the first portion (e.g., the output of non-inverting buffer 456) being coupled to the input of inverter 464 and the second portion (e.g., the output of non-inverting buffer 466) being coupled to the input of output logic block 440. The inverter 464 is arranged to place the clock signal into a state that is the complement of the state of the output inverter 466.

Input logic circuit 420 is arranged to propagate a logic output signal to an input of combinatorial logic 430 in response to the received clock signal. Output logic block 440 is arranged, for example, to latch an output from combinatorial logic 430 in response to the clock input signal received from the output of inverter 466. Accordingly, the PMOS transistors in the first portion of the clock-tree 450 are aged evenly (due to NBTI-induced aging) with respect to the PMOS transistors and the second portion of the clock-entry 450. Likewise, the NMOS transistors in the first portion of the clock-tree 450 are aged evenly (due to PBTI-induced aging) with respect to the NMOS transistors and the second portion of the clock-entry 450. Accordingly, the symmetric aging of the transistors in clock-tree 450 reduces the likelihood that the output logic block 440 may erroneously latch the state of the output from combinatorial logic 430.

The midpoint between the first portion and the second portion of the clock tree is around the halfway point of the path of the propagated clock signal through the clock tree. Depending on whether the total number of buffers in the clock tree is odd or even, the midpoint may be selected such that the number of PMOS transistors in each portion is equal, or that the number of PMOS transistors in one portion is one greater than the number of PMOS transistors in the other portion. As discussed herein, the midpoint can be move further from the halfway point of propagation, although the NBTI-induced aging effects will become progressively less symmetric as the midpoint is shifted away from the halfway point of propagation.

Because clock buffers in a clock tree can have differing propagation delays (such as by using differing gate configurations in the transistors thereof), the determination of the halfway point of propagation can be made by measurement or simulations. Thus, the exact location of the halfway point is an approximation and described using terms such as “about” or “around.” A substantial amount of displacement of the midpoint from the ideal halfway way point can be defined as a location at which a reduction in NBTI-induced aging effects in a clock tree can be measured (after, for example, a NBTI-resistant circuit has been aged). Some NBTI-induced aging effects can be determined (for example) by measuring degradation of the maximum operating frequency of the clock propagated by the clock-tree.

When clock-tree 450 is gated such that the output of clock-tree 450 is a logic zero, either the first portion of the clock-tree 450 is degraded or the second portion of the clock-tree 450 is degraded over time. In the example set of operating conditions, the clock skew of clock-tree 450 due to NBTI-induced aging is thus limited to be around five percent (which is half of the estimated clock skew of circuit 300) between the launch (e.g., a first transition of the output of input clock buffer 410) and the capture clock (e.g., the first transition of the input of output logic block 440).

The more equal the length of each of the length of the two portions of the clock-tree 450 is, the less likely that the each portion being aged at 50 percent on and 50 percent off would age unevenly. Thus, for example, when applying the example set of operating conditions to a clock-tree having one portion with three buffers and a second portion having two buffers, the clock skew of clock-tree 450 due to NBTI-induced aging is thus limited to be around six percent. Likewise, when applying the example set of operating conditions to a clock-tree having one portion with four buffers and a second portion having one buffer, the clock skew of clock-tree 450 due to NBTI-induced aging is limited to be around eight percent.

Accordingly, the clock tree 450 includes a first series of logic gates such as delay buffers (e.g., 552, 554, and 556) coupled end-to-end between the starting point and the midpoint and a second series of logic gates such as delay buffers (e.g., 458, 460, and 462) coupled end-to-end between the midpoint and the endpoint. Each delay buffer includes a first and a second inverter (as illustrated in FIG. 2), where the output of the first inverter in each delay buffer is coupled to the input of the second inverter in each delay buffer. Thus, the PMOS (P-type metal-oxide silicon) transistor of the first inverter in a delay buffer of the first series has a conductive state that is the complement of the conductive state of the first inverter in a delay buffer of the second series.

FIG. 5 is a schematic diagram illustrating a circuit that includes a secondary clock gate insertion NBTI-resistant clock-tree 500 in accordance with embodiments of the disclosure. Circuit 500 includes an input clock buffer 510. Input clock buffer 510 is arranged to couple the clock signal to input logic circuit 520 as well as to a clock-tree 550 formed by non-inverting buffers 552, 554, 556, 558, 560, and 562. The clock-tree 550 is divided into two portions with the first portion (e.g., the output of non-inverting buffer 556) being coupled to the input of gated inversion block 564. The gated inversion block 564 has a first input that is coupled to the clock signal and a second input that is coupled to an inversion of the clock signal and a select input that is coupled to a clock gating signal (such as the “enable” signal). The clock gating signal in an active mode is arranged to conserve power, such as by gating the clock signal so that clock buffers do not transition. The gated inversion block 564 is arranged to act as a non-inverting buffer when the clock signal is in a free-running mode, and is arranged to act as an inverter when the clock signal is being gated (e.g., in a gated mode where the clock signal does not transition).

Input logic circuit 520 is arranged to propagate a logic output signal to an input of combinatorial logic 530 in response to the received clock signal. Output logic block 540 is arranged, for example, to latch an output from combinatorial logic 530 in response to the clock input signal received from the output of non-inverting buffer 562. Accordingly, the PMOS transistors in the first portion of the clock-tree 550 are aged evenly (due to NBTI-induced aging) with respect to the PMOS transistors and the second portion of the clock-entry 550. Likewise, the NMOS transistors in the first portion of the clock-tree 550 are aged evenly (due to PBTI-induced aging) with respect to the NMOS transistors and the second portion of the clock-entry 550. Accordingly, the symmetric aging of the transistors in clock-tree 550 reduces the likelihood that the output logic block 540 may erroneously latch the state of the output from combinatorial logic 530.

When clock-tree 550 is gated such that the output of clock-tree 550 is a logic zero, either the first portion of the clock-tree 550 is degraded or the second portion of the clock-tree 550 is degraded over time. In the example set of operating conditions, the clock skew of clock-tree 550 due to NBTI-induced aging is thus limited to be around five percent (which is half of the estimated clock skew of circuit 300) between the launch (e.g., a first transition of the output of input clock buffer 510) and the capture clock (e.g., the first transition of the input of output logic block 540).

FIG. 6 is a schematic diagram illustrating a circuit that includes clock-tree non-equivalent gate insertion NBTI-resistant clock-tree 600 in accordance with embodiments of the disclosure. Circuit 600 includes an input clock buffer 610. Input clock buffer 610 is arranged to couple the clock signal to input logic circuit 620 as well as to a clock-tree 650 formed by non-inverting buffers 652, 654, 656, 658, 660, and 662. The clock-tree 650 is divided into two portions with the first portion (e.g., the output of non-inverting buffer 656) being coupled to the input of exclusive-OR (XOR, e.g., which is a “non-equivalence”) gate 664. The XOR gate 664 has a first input that is coupled to the clock signal and a second input that is coupled to the clock gating signal. The XOR gate 664 is arranged to act as a non-inverting buffer when the clock signal is in a free-running mode, and is arranged to act as an inverter when the clock signal is being gated (e.g., in a gated mode where the clock signal does not transition).

Input logic circuit 620 is arranged to propagate a logic output signal to an input of combinatorial logic 630 in response to the received clock signal. Output logic block 640 is arranged, for example, to latch an output from combinatorial logic 630 in response to the clock input signal received from the output of non-inverting buffer 662. Accordingly, the PMOS transistors in the first portion of the clock-tree 650 are aged evenly (due to NBTI-induced aging) with respect to the PMOS transistors and the second portion of the clock-entry 650. Likewise, the NMOS transistors in the first portion of the clock-tree 650 are aged evenly (due to PBTI-induced aging) with respect to the NMOS transistors and the second portion of the clock-entry 650. Accordingly, the symmetric aging of the transistors in clock-tree 650 reduces the likelihood that the output logic block 640 may erroneously latch the state of the output from combinatorial logic 630.

When clock-tree 650 is gated such that the output of clock-tree 650 is a logic zero, either the first portion of the clock-tree 650 is degraded or the second portion of the clock-tree 650 is degraded over time. In the example set of operating conditions, the clock skew of clock-tree 650 due to NBTI-induced aging is thus limited to be around five percent (which is half of the estimated clock skew of circuit 300) between the launch (e.g., a first transition of the output of input clock buffer 610) and the capture clock (e.g., the first transition of the input of output logic block 640).

Although the NBTI-resistant devices disclosed herein have been described with two portions in a clock tree, the clock tree can be, for example, divided into four groups (by using an inverters placed after each groups) to mitigate NBTI-aging effects of an NBTI-resistant device such as a forced quad-inversion NBTI-resistant clock-tree. Likewise multiple clock gate insertions can be performed using four clock tree groups as well as multiple clock-tree non-equivalent gate insertions can be performed using four clock tree groups to produce an NBTI-resistant clock-tree. Higher multiple numbers of clock tree groups can be used.

The various embodiments described herein may be implemented using positive and/or negative logic and/or using complementary types (e.g., P-type MOS and N-type MOS) of the transistors shown in the various embodiments. For example, the clock tree 230 and the clock tree 250 also undergo PBTI-aging when the clock signal is gated. For example, the NMOS transistor in inverter 232 also accumulates 100 kPOH in similar fashion to the PMOS transistor in inverter 234. Thus, both PBTI- and NBTI-aging are encountered by complementary transistors in pairs of inverters. Likewise, the NMOS transistor in inverter 252 also accumulates 100 kPOH in similar fashion to the PMOS transistor in inverter 254.

The various embodiments described above are provided by way of illustration only and should not be construed to limit the claims attached hereto. Those skilled in the art will readily recognize various modifications and changes that could be made without following the example embodiments and applications illustrated and described herein, and without departing from the true spirit and scope of the following claims.

What is claimed is:

1. A Bias Temperature Instability- (BTI-) resistant device, comprising
a first group of at least one logic gate that is arranged to output a received clock signal that is received at the input of the first group of logic gates;
a BTI mitigation gate that is arranged to receive the clock signal output by the first group of logic gates and is arranged to generate a mitigated clock signal by changing the state of the received clock signal output to mitigate BTI-aging effects of the BTI-resistant device when the clock signal is blocked by a clock gating signal; and
a second group of at least one logic gate that is arranged to receive the mitigated clock signal and to generate an output clock signal in response to the received mitigated clock signal.

2. The device of claim 1, wherein transistors of at least one logic gate of each of the first and second groups include PMOS (P-type metal-oxide silicon) transistors.

3. The device of claim 1, comprising combinatorial logic that latches an input to the combinatorial logic using the received clock signal and that latches an output signal of the combinatorial logic using the output clock signal.

4. The device of claim 1, wherein each logic gate includes an input and an output CMOS (complementary metal-oxide silicon) inverter coupled in series, wherein exactly one of the PMOS transistors undergoes Negative Bias Temperature Instability- (NBTI-) induced aging effects when the exactly one of the PMOS transistors is in an on state.

5. The device of claim 4, wherein the mitigated clock signal is generated to place the input inverter of a logic gate in the second group of at least one logic gate into a state that is the opposite of the state of the input inverter of a logic gate in the first group of at least one logic gate.

6. The device of claim 5, wherein the mitigated clock signal is generated to place the output inverter of a logic gate in the second group of at least one logic gate into a state that is the opposite of the state of the output inverter of a logic gate in the first group of at least one logic gate.

7. The device of claim 1, wherein the BTI mitigation gate is an inverter.

8. The device of claim 7, comprising combinatorial logic that is arranged to latch an input signal using the received clock signal and to latch an output signal using the output clock signal and comprising an inverter that is coupled between the output of the last logic gate in the second group and the input of the combinatorial logic and that is arranged to invert the inverted logic state of the second group of logic gates.

9. The device of claim 1, wherein the number of PMOS (P-type metal-oxide silicon) transistors in the first group is the same as the number of PMOS transistors in the second group.

10. The device of claim 1, wherein the number of PMOS (P-type metal-oxide silicon) transistors in the first group is the one more than the number of PMOS transistors in the second group.

11. The device of claim 1, wherein the mitigated clock signal is generated when the clock gating signal is active.

12. The device of claim 11, wherein the mitigated clock signal is generated by an exclusive-OR (XOR) gate having a first input coupled to the clock signal and a second input coupled to the clock gating signal.

13. The device of claim 12, wherein the mitigated clock signal is generated by a multiplexor having a first input coupled to the clock signal and a second input coupled to an inversion of the clock signal and a select input that is coupled to the clock gating signal.

14. A Bias Temperature Instability- (BTI-) resistant circuit, comprising:
a first segment of a clock tree having at least one logic gate that is arranged to output a received clock signal that is received at the input of the first group of logic gates;
a BTI mitigation gate that is arranged to receive the clock signal output by the first group of logic gates and is arranged to generate a mitigated clock signal by changing the state of the received clock signal output to mitigate BTI-aging effects of the BTI-resistant circuit when the clock signal is blocked by a clock gating signal; and
a second segment of the clock tree at least one logic gate that is arranged to receive the mitigated clock signal and to generate an output clock signal in response to the received mitigated clock signal, wherein the BTI mitigation gate is placed at a location in the clock tree that is around the half-way propagation point of the clock signal in the clock tree.

15. The circuit of claim 14, wherein the BTI mitigation gate is placed at a location in the clock tree that is closest to the half-way propagation point of the clock signal in the clock tree.

16. The circuit of claim 14, wherein the mitigated clock signal is generated when the clock gating signal is active.

17. A method for equalizing Bias Temperature Instability- (BTI-) degradation in clock trees, comprising;
propagating a received clock signal through a clock tree, wherein the clock signal is respectively propagated through a starting point, a midpoint, and an endpoint of the clock tree;
inverting the state of the clock signal at the midpoint to mitigate BTI-aging effects of the BTI-resistant circuit when the clock signal is blocked by a clock gating signal; and
latching a data signal at an input latch of a logic block using the received clock signal, and latching a data signal at an output latch of a logic block using a propagated clock signal that is output from the endpoint of the clock tree.

18. The method of claim 17, wherein the clock tree includes a first series of delay buffers coupled end-to-end between the starting point and the midpoint and a second series of delay buffers coupled end-to-end between the midpoint and the endpoint, wherein each delay buffer includes a first and a second inverter, wherein the output of the first inverter in each delay buffer is coupled to the input of the second inverter in each delay buffer, wherein the NMOS (N-type metal-oxide silicon) transistor of the first inverter in a delay buffer of the first series has a conductive state that is the complement of the conductive state of the first inverter in a delay buffer of the second series.

19. The method of claim 18, wherein the midpoint is around the half-way point of the path of the propagated clock signal through the clock tree.

20. The method of claim 19, wherein the NMOS (N-type metal-oxide silicon) transistor of the first inverter in a delay buffer of the first series has a conductive state that is the same of the conductive state of the first inverter in a delay buffer of the second series when the clock gating signal is not active.
